(19) United States
(12) Patent Application Publication
(10) Pub. No.: US 2002/0164857 A1
(43) Pub. Date: Nov. 7, 2002

(54) Method for forming dual gate of a semiconductor device

(75) Inventor: Jae-hee Ha, Chungju (KR)

Correspondence Address: MARSHALL, GERSTEIN & BORUN, 6300 SEARS TOWER, 233 SOUTH WACKER, CHICAGO, IL, 60606-6357, US

(73) Assignee: Hynix Semiconductor Inc., Gyunggi-do (KR)

(21) Appl. No.: 10/116,833

(22) Filed: Apr. 5, 2002

(30) Foreign Application Priority Data
Apr. 6, 2001 (KR) 2001-18403

(51) Int. Cl. H01L 21/336

(52) U.S. Cl. 438/283; 438/297

(57) ABSTRACT

A method for forming a dual gate of a semiconductor devices by etching the polysilicon layer as a multi-step, resulting in etching velocities and anisotropic etching profiles for doped polysilicon and undoped polysilicon that are consistent and, since there is no difference in etching selectivity in the following etching step, damage of gate oxide layer by excess etching is prevented.

### BACKGROUND

1. Technical Field

A method for forming a dual gate of a semiconductor device is disclosed. In particular, by etching a polysilicon layer using a multi-step process, etching velocities and anisotropic etching profiles for doped polysilicon and undoped polysilicon are consistent and, since there is no difference in etching selectivity in the following etching step, damage of the gate oxide layer by excess etching is prevented.

2. Description of the Related Art

In general, a gate of an ultramicro semiconductor device is formed by the steps of depositing the undoped polysilicon, injecting N+ ions or P+ ions to form a doped polysilicon, and performing a photoresist process and then an etching process.

Since the properties of a semiconductor device such as threshold voltage are affected by the width of a gate line, the consistencies of critical dimensions are required.

Also, a high etching selectivity of a gate polysilicon is required because the thickness of a gate oxide layer on a silicon substrate is decreased down to 100% as a semiconductor device becomes highly integrated. Therefore, the etched wall of the gate should be as perpendicular as possible and the etching conditions for high selectivity are necessary in the etching process for a doped polysilicon to form a dual gate. From this point, a conventional art for forming a dual gate of a semiconductor device will be described referring to appended FIGS. 1a to 1c. As illustrated in FIG. 1a, an undoped polysilicon (not shown) is deposited after forming a gate oxide layer 5 on a semiconductor substrate defined an active region and a field region by forming a field oxide layer 3. By the injection of N+ ions after dividing the undoped polysilicon layer, an N-doped polysilicon layer 9 doped by N+ ions and an undoped polysilicon layer 7 are defined. And then, dual gate mask patterns 11 are formed on the N-doped polysilicon layer 9 and the undoped polysilicon layer 7.

As illustrated in FIG. 1b, the N-doped polysilicon layer 9 and the undoped polysilicon layer 7 are etched until the top of the gate oxide layer 5 is exposed by using the dual mask patterns 11 and plasma with chlorine/bromine and inert gas, thereby forming a dual gate.

There are several problems in that the side wall of the N-doped polysilicon layer 9 is etched excessively at the area indicated at “A” by the limited selectivity of etching gases and the part of the undoped polysilicon layer 7 remained on the top of the gate oxide layer 5 due to difference of etching selectivities for the N-doped polysilicon layer 9 and the undoped polysilicon layer 7. Therefore, as illustrated in FIG. 1c, the dual gate is formed by removing the dual gate mask patterns 11 after the excess etching of the undoped polysilicon layer 7 by using the dual gate mask patterns 11 and plasma with mixed gases of chlorine/bromine and a large amount of inert gas under the high selectivity etching condition.

There is also a problem in that the excess etching causes serious damage to the area indicated at “B” on the gate oxide layer 5 of the N-doped polysilicon layer 9 region due to the slow etching velocity for the undoped polysilicon layer 7.

### SUMMARY OF THE INVENTION

The disclosed methods solve the above problems and prevent damage of a gate oxide layer by the excess etching caused by the difference in etching selectivity. A multi-step etching process is disclosed which can keep the etching velocities and the anisotrophic etching profiles for the doped polysilicon and the undoped polysilicon consistent and the etching selectivities to the gate oxide layer at the bottom are same in the following etching step.

A disclosed method of forming a dual gate of a semiconductor device comprises: depositing an undoped polysilicon after forming a gate oxide layer on a semiconductor substrate defined active and field regions through the formation of a field oxide layer; defining an N-doped polysilicon region and an undoped polysilicon region by injecting N+ ion into the other side of the top of the undoped polysilicon after forming a photoresist mask on a side of the top of the undoped polysilicon; forming a dual gate mask pattern on the top portion of the N-doped polysilicon and undoped polysilicon regions; and forming a dual gate by removing the dual gate mask pattern after etching the N-doped polysilicon and undoped polysilicon by a multi-step etching process.

Preferably, a multi-step etching process comprises a first etching for performing a photo etching by using plasma mixed with fluorine-containing gas and halogen gas, a second etching for etching until the gate oxide layer is exposed by using gas mixed with halogen gas and inert gas and a third etching for etching the N-doped polysilicon and undoped polysilicon excessively with the etching condition of high selectivity to the gate oxide layer by using gas mixed with halogen gas and inert gas.

Preferably, the first etching step is a photo etching step that etches 65-80% of the thickness of the N-doped polysilicon and the undoped polysilicon is etched under a pressure ranging from about 2 to about 30 mTorr with a fluorine-containing gas selected from the group consisting of CF₄, CHF₃, C₂F₆, C₃F₈ and C₄F₈ and the fluorine-containing gas represents from about 5 to about 25% of total flow volume used.

Preferably, the inert gas used in the second and third etching steps comprises one or more gases selected from the group consisting of He, Ar, N2 or O2 and an comprises amount of the inert gas added in the third etching step is greater than that of the second etching step.

### BRIEF DESCRIPTION OF THE DRAWINGS

The above objects, features and advantages of the disclosed methods will become more apparent from the following detailed description when taken in conjunction with the accompanying drawings wherein:

FIGS. 1a to 1c are cross-sectional views illustrating a conventional method of forming a dual gate of a semiconductor device; and

FIGS. 2a to 2e are cross-sectional views illustrating a method of forming a dual gate of a semiconductor device according to this disclosure.

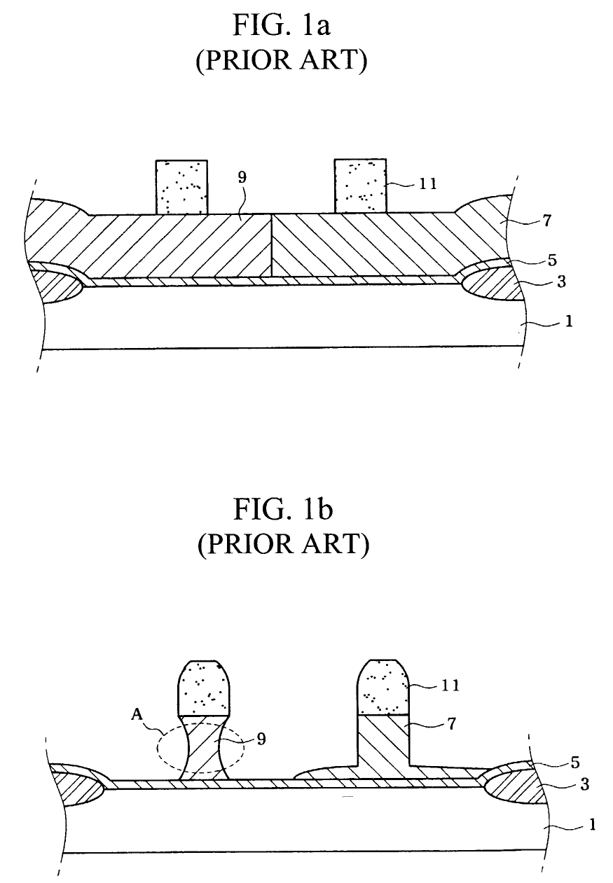

### DESCRIPTION OF THE PRESENTLY PREFERRED EMBODIMENTS

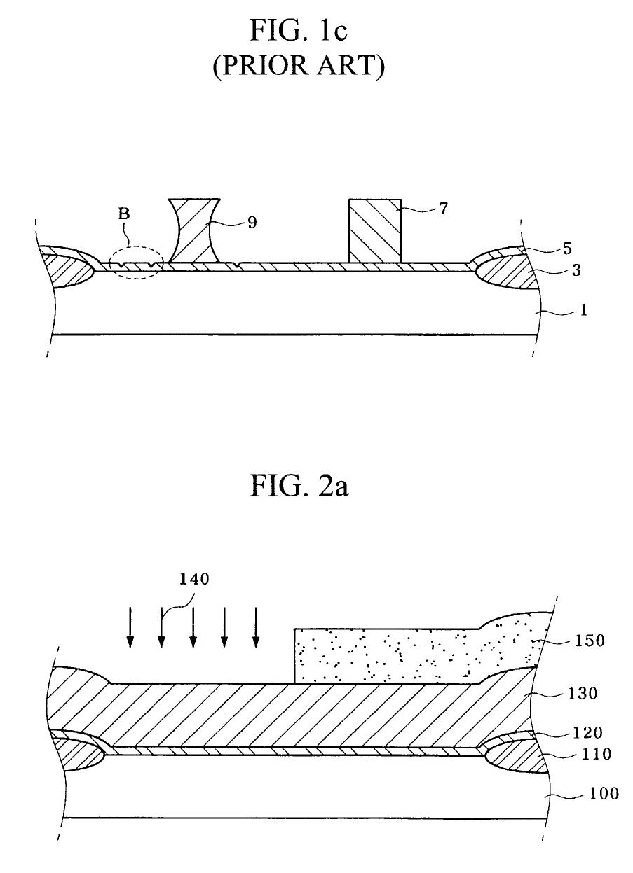

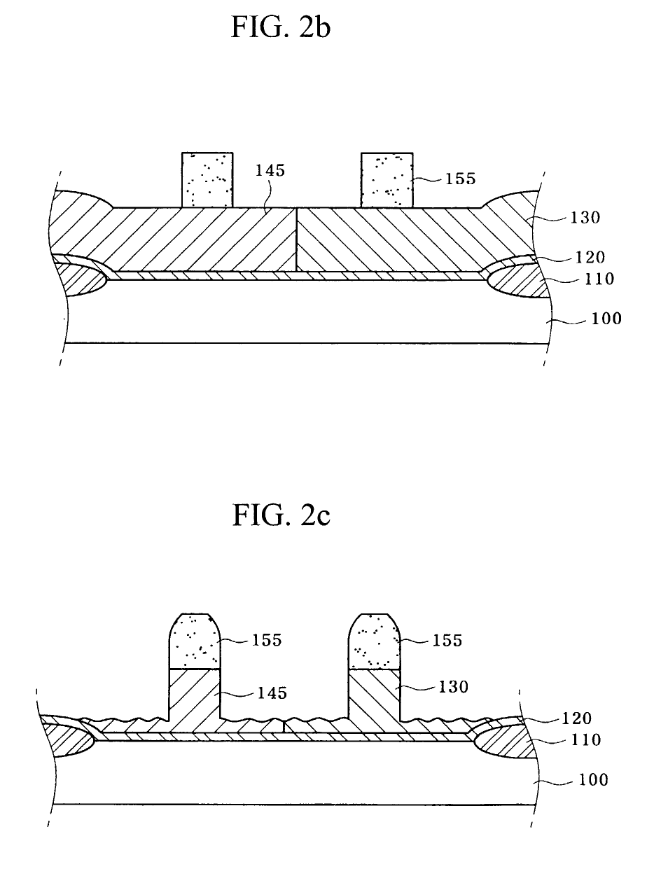

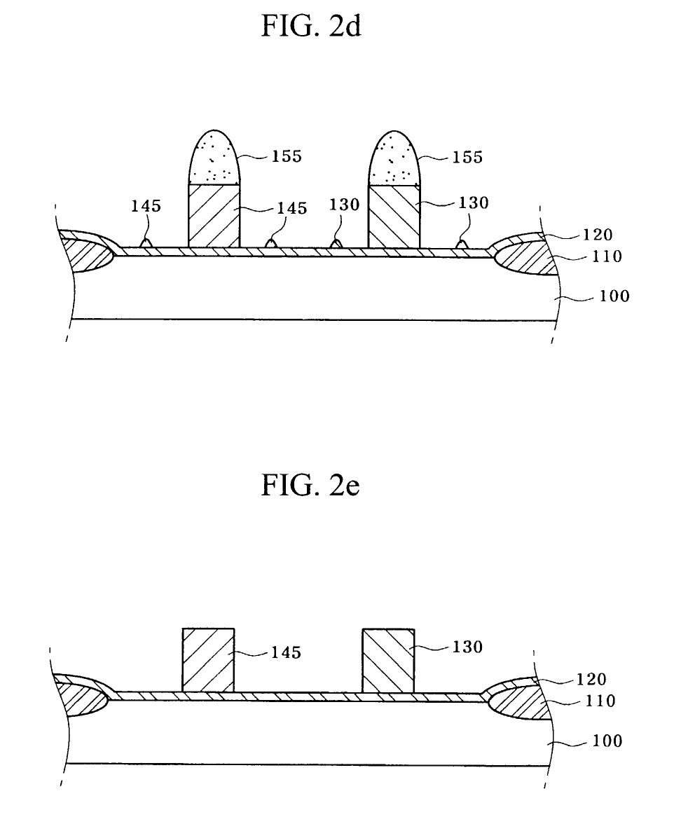

FIGS. 2a to 2e are cross-sectional views illustrating a method of forming a dual gate of semiconductor device according to this disclosure. As illustrated in FIG. 2a, an undoped polysilicon 130 is deposited after forming a gate oxide layer 120 on a semiconductor substrate 100 defined an active region and a field region by forming a field oxide layer 10. After forming a photoresist mask 150 on a side of the top (on a half of right side) of the undoped polysilicon layer 130, N-doped polysilicon and undoped polysilicon regions are formed by injecting N+ ion 140 on the other side (on a half of left side) of the top of the undoped polysilicon layer 130.

As illustrated in FIG. 2b, at the top of the N-doped polysilicon 145 and undoped polysilicon 130 regions, dual gate mask patterns 155 are masked for the formation of the dual gate.

As illustrated in FIG. 2c, a photo etching is performed by using the dual gate mask patterns 155 and plasma mixed with fluorine-containing gas and halogen gas as a first etching step.

In the first etching step, from about 65 to about 80% of the N-doped polysilicon and the undoped polysilicon in thickness is etched at a pressure ranging from about 2 to about 30 mTorr and the fluorine-containing gas represents from about 5 to about 25% of total flow volume used. The fluorine-containing gas comprises one or more gases selected from the group consisting of CF₄, CHF₃, C₂F₆, C₃F₈ and C₄F₈ Since the difference of etching velocities between the N-doped polysilicon region 145 and the undoped polysilicon region 130 is decreased in a plasma mixed with fluorine-containing gas and a halogen gas due to a decreased etching selectivity, the etching velocities and anisotrophic etching profiles are consistent.

As shown in FIG. 2d, a second etching step is performed until the gate oxide layer 120 is exposed by using the dual gate mask patterns 155 and mixing halogen gas with inert gas. At this time, the inert gas comprises at least one or more gases selected from the group consisting of He, Ar, N₂ or O₂.

Continuously, as shown in FIG. 2e, as a third etching step, the N-doped polysilicon 145 and the undoped polysilicon 130 are etched excessively by using the dual gate mask patterns 155 and mixing halogen gas with inert gas in high etching selectivity of 60:1 to the gate oxide layer. The inert gas comprises at least one or more gases selected from the group consisting of He, Ar, N₂ or O₂ and the amount of inert gas is increased as compared to the amount of inert gas used in the second etching step. The amount of inert gas used in the third etching step ranges from about 5 to about 15 sccm. Finally, the dual gate is formed by removing the dual gate mask patterns (not shown) on the N-doped polysilicon 145 and the undoped polysilicon 130.

By etching the polysilicon layer as a multi-step, etching velocities and anisotropic etching profiles for the doped polysilicon and the undoped polysilicon are consistent and since there is no difference in etching selectivity in the following etching step, damage of a gate oxide layer by an excess etching is prevented. And since critical dimensions of the dual gates are uniform, the properties of a semiconductor device are improved.

As the disclosed method may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the meets and bounds of the claims, or equivalencies of such meets and bounds are therefore intended to be embraced by the appended claims.

What is claimed is:

1. A method of forming a dual gate of a semiconductor device, the method comprising:
forming a gate oxide layer on a semiconductor substrate having defined active and field regions by a prior formation of a field oxide layer;
depositing an undoped polysilicon layer on the gate oxide layer;
forming a photoresist mask on one side of a top surface of the undoped polysilicon layer;
defining an N-doped polysilicon region and an undoped polysilicon region by injecting N+ ion into another side of the top surface of the undoped polysilicon layer not covered by the photoresist mask;
forming a dual gate mask pattern on top of the N-doped polysilicon and undoped polysilicon regions; and
forming a dual gate by removing the dual gate mask pattern after etching the N-doped polysilicon and undoped polysilicon with a multi-step etching process.

2. The method of claim 1, wherein the multi-step etching process comprises: first-etching by performing a photo etching by using a plasma comprising a fluorine-containing gas and a halogen gas; second-etching by etching until the gate oxide layer is exposed by using a gas mixture comprising a halogen gas and an inert gas; and third-etching by etching the N-doped polysilicon and undoped polysilicon requires excessively with an etching condition of a high selectivity to the gate oxide layer by using a gas mixture comprising a halogen gas and an inert gas.

3. The method of claim 2, wherein the photo etching of the first-etching results in a thickness reduction ranging from about 65 to about 80% of the thickness of the N-doped polysilicon and the undoped polysilicon regions.

4. The method of claim 2, wherein the first-etching step is performed at pressure ranging from about 2 to about 30 mTorr.

5. The method of claim 2, wherein the fluorine-containing gas comprises at least one gas selected from the group consisting of CF₄, CHF₃, C₂F₆, C₃F₈, C₄F₈ and mixtures thereof.

6. The method of claim 2, wherein the fluorine-containing gas represents from about 5 to about 25% of a total flow volume.

7. The method of claim 2, wherein the inert gas used in the second and third etchings is at least one gas selected from the group consisting of He, Ar, N2, O2 and mixtures thereof.

8. The method of claim 2, wherein an amount of the inert gas added in the third-etching step is greater than that of the second-etching step.

9. A method of forming a dual gate of a semiconductor device, the method comprising:
forming a gate oxide layer on a semiconductor substrate having defined active and field regions by a prior formation of a field oxide layer;
depositing an undoped polysilicon layer on the gate oxide layer;
forming a photoresist mask on one side of a top surface of the undoped polysilicon layer;
defining an N-doped polysilicon region and an undoped polysilicon region by injecting N+ ion into another side of the top surface of the undoped polysilicon layer not covered by the photoresist mask;
forming a dual gate mask pattern on top of the N-doped polysilicon and undoped polysilicon regions;
first-etching the N-doped and undoped polysilicon regions by performing a photo etching by using the dual gate mask pattern and a plasma comprising fluorine-containing gas and a halogen gas;
second-etching by etching until the gate oxide layer beneath the N-doped and undoped polysilicon regions is exposed using the dual gate mask pattern and a gas comprising a halogen gas and an inert gas;
third-etching by etching the N-doped polysilicon and undoped polysilicon regions excessively with an etching condition of high selectivity to the gate oxide layer by using the dual gate mask pattern and a gas comprising a halogen gas and an inert gas; and
forming a dual gate by removing the dual gate mask pattern.

10. The method of claim 9, wherein the photo etching in the first-etching results in a thickness reduction ranging from about 65 to about 80% of the N-doped polysilicon and the undoped polysilicon regions.

11. The method of claim 9, wherein the first-etching step is performed at a pressure ranging from about 2 to about 30 mTorr.

12. The method of claim 9, wherein the fluorine-containing gas comprises at least one gas selected from the group consisting of CF₄, CHF₃, C₂F₆, C₃F₈, C₄F₈ and mixture thereof.

13. The method of claim 9, wherein an amount of the fluorine-containing gas represents from about 5 to about 25% of a total flow volume.

14. The method of claim 9, wherein the inert gas used in the second and third etching steps comprises at least one gas selected from the group consisting of He, Ar, N₂, O₂ and mixtures thereof.

15. The method of claim 9, wherein an amount of the inert gas added in the third etching step is greater than that of the second etching step.
